(19) United States
(12) Patent Application Publication
(10) Pub. No.: US 2026/0050042 A1
(43) Pub. Date: Feb. 19, 2026

(54) STATE-OF-CHARGE ESTIMATION DEVICE, STATE-OF-CHARGE ESTIMATION SYSTEM, AND STATE-OF-CHARGE ESTIMATION PROGRAM

(71) Applicant: DENSO CORPORATION, Kariya-City (JP)

(72) Inventors: Yusuke WATANABE, Kariya-City (JP); Masaki Uchiyama, Kariya-City (JP); Yuki Hori, Kariya-City (JP)

(73) Assignee: DENSO CORPORATION, Kariya-City (JP)

(21) Appl. No.: 19/371,300

(22) Filed: Oct. 28, 2025

Related U.S. Application Data
(63) Continuation of application No. PCT/JP2024/013565, filed on Apr. 2, 2024.

(30) Foreign Application Priority Data
Apr. 28, 2023 (JP) 2023-074306

(51) Int. Cl. G01R 31/3828; B60L 50/60; B60L 53/10; B60L 53/62; G01R 31/396

(52) U.S. Cl. CPC G01R 31/3828; B60L 50/60; B60L 53/11; B60L 53/62; G01R 31/396; B60L 2210/10; B60L 2210/42

(57) ABSTRACT

A state-of-charge estimation device includes: a storage unit that stores the charge and discharge history of a storage battery; a charge and discharge determination unit that determines whether the storage battery is in a charged state or a discharged state; a charge and discharge control unit that discharges the storage battery by a predetermined amount when the charge and discharge determination unit determines that the storage battery is in a charged state, and charges the storage battery by a predetermined amount when the charge and discharge determination unit determines that the storage battery is in a discharged state; an open-circuit voltage acquisition unit that acquires the open-circuit voltage of the storage battery; and a state-of-charge estimation unit that refers to a charge and discharge curve to estimate the state of charge of the storage battery from the open-circuit voltage acquired by the open-circuit voltage acquisition unit.

### CROSS-REFERENCE OF RELATED APPLICATIONS

This application is the U.S. bypass application of International Application No. PCT/JP2024/013565 filed on Apr. 2, 2024, which designated the U.S. and claims priority to Japanese Patent Application No. 2023-074306 filed on Apr. 28, 2023, and the contents of both of these are incorporated herein by reference.

### BACKGROUND

### Technical Field

The present disclosure relates to a state-of-charge estimation device that estimates the state of charge of a storage battery, a state-of-charge estimation system, and a state-of-charge estimation program.

### Description of the Related Art

Techniques are conventionally known for estimating the state of charge (SOC) of a storage battery from the open-circuit voltage (OCV) of the battery. Such techniques include a technique implemented based on the difference between the charging curve, which is the OCV-SOC curve observed during storage battery charging, and the discharging curve, which is the OCV-SOC curve observed during storage battery discharging, that is, the hysteresis characteristics of the storage battery. For example, a technique is designed to estimate the SOC from the OCV based on the charging curve each time after the battery is charged.

### SUMMARY

First means of the present disclosure is a state-of-charge estimation device for estimating the state of charge of a storage battery. The state-of-charge estimation device includes: a storage unit that stores the charge and discharge history of the storage battery; a charge and discharge determination unit that determines whether the storage battery is in a charged state or a discharged state, based on the charge and discharge history stored in the storage unit; a charge and discharge control unit that discharges the storage battery by a predetermined amount when the charge and discharge determination unit determines that the storage battery is in a charged state, and charges the storage battery by a predetermined amount when the charge and discharge determination unit determines that the storage battery is in a discharged state; an open-circuit voltage acquisition unit that acquires the open-circuit voltage of the storage battery after the charge and discharge control unit charges or discharges the storage battery; and a state-of-charge estimation unit that refers to a charge and discharge curve indicating the relationship between the open-circuit voltage of the storage battery and the state of charge of the storage battery to estimate the state of charge of the storage battery from the open-circuit voltage acquired by the open-circuit voltage acquisition unit.

### BRIEF DESCRIPTION OF THE DRAWINGS

The above and other objectives, features, and advantages of the present disclosure will become more clearly apparent from the detailed description given below with reference to the accompanying drawings, in which:

FIG. 1 is a configuration diagram of a power supply system according to a first embodiment;

FIG. 2(a) is a diagram showing errors in OCV after charging, and FIG. 2(b) is a diagram showing errors in OCV after discharging;

FIG. 3 is a diagram showing OCV-SOC curves;

FIG. 4 is a flowchart of a storage process;

FIG. 5 is a flowchart of an SOC estimation process;

FIG. 6 is a timing chart showing charge and discharge timing;

FIG. 7 is a configuration diagram of a power supply system according to a modification;

FIG. 8 is a configuration diagram of a power supply system according to a modification; and

FIG. 9 is a flowchart of a storage process according to a modification.

### DETAILED DESCRIPTION OF THE PREFERRED EMBODIMENTS

Techniques are conventionally known for estimating the state of charge (SOC) of a storage battery from the open-circuit voltage (OCV) of the battery. For example, JP 2020-38146 A discloses such techniques including a technique implemented based on the difference between the charging curve, which is the OCV-SOC curve observed during storage battery charging, and the discharging curve, which is the OCV-SOC curve observed during storage battery discharging, that is, the hysteresis characteristics of the storage battery. For example, a technique is designed to estimate the SOC from the OCV based on the charging curve each time after the battery is charged.

In these techniques, it has been found that an error occurs in the OCV between high and low C (Capacity) rates during charge and discharge. This trend is particularly pronounced in LFP (lithium iron phosphate) batteries. SOC estimation based on OCV values containing an error may result in reduced SOC estimation accuracy.

Storage batteries used in electric vehicles need high-rate characteristics (high-current charge and discharge). For example, fast charging using a fast charger involves a higher C-rate than standard charging with regular chargers installed in households and similar areas. That is, such a storage battery is expected to experience a larger OCV error induced by different C-rates. Accordingly, a larger SOC error is expected to occur, and thus fast charging may not be properly completed when controlled based on the SOC.

Hereinafter, with reference to the drawings, embodiments of the present disclosure will be described.

A first embodiment of a state-of-charge estimation device, a state-of-charge estimation system, and a state-of-charge estimation program according to the present disclosure will now be described with reference to the drawings. In the embodiments and modifications described below, the same or equivalent components are given the same reference numerals throughout the drawings, and the description of components designated by the same reference numerals is incorporated by reference. A power supply system 100 serving as a state-of-charge estimation system according to the present embodiment is installed in mobility systems, including electrified vehicles such as electric vehicles and hybrid vehicles, electric aircraft, and electric ships. The present embodiment assumes installation in electrified vehicles.

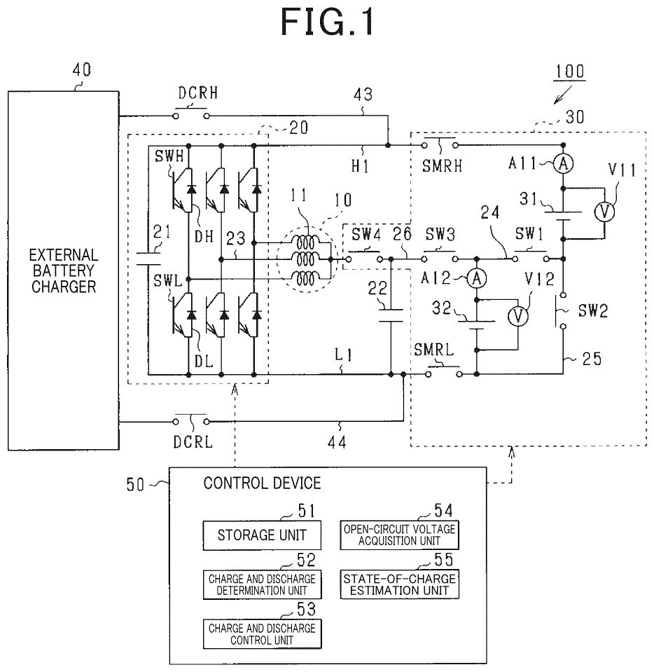

As shown in FIG. 1, the power supply system 100 includes a motor 10, an inverter 20, and a battery pack 30. The motor 10 is a three-phase synchronous motor and includes star-connected U-, V-, and W-phase armature windings 11 and a rotor (not shown). The armature winding 11 of each phase is spaced 120 electrical degrees from the others. The motor 10 may be, for example, a permanent-magnet synchronous motor. The rotor can transmit power to the drive wheels of the vehicle. The motor 10 thus serves as the source of torque for driving the vehicle.

The inverter 20 includes three-phase series-connection bodies each having an upper arm switch SWH and a lower arm switch SWL. An upper arm diode DH that is a freewheeling diode is connected in antiparallel with the upper arm switch SWH, whereas a lower arm diode DL that is a freewheeling diode is connected in antiparallel with the lower arm switch SWL. Hereinafter, the upper arm switch SWH and the lower arm switch SWL are sometimes collectively referred to as the switches SWH and SWL. In the present embodiment, each of the switches SWH and SWL is a semiconductor switching element, such as insulated gate bipolar transistor (IGBT).

The inverter 20 includes a smoothing capacitor 21. The high-potential terminal of the smoothing capacitor 21 is connected to a positive busbar H1. The low-potential terminal of the smoothing capacitor 21 is connected to a negative busbar L1. Note that the smoothing capacitor 21 may be installed outside the inverter 20.

In each phase, the connection point between the low-potential terminal of the upper arm switch SWH, or the emitter, and the high-potential terminal of the lower arm switch SWL, or the collector, is connected with a first end of the corresponding armature winding 11 via a conductive member 23 such as a bus bar. The armature windings 11 in the respective phases have second ends connected to each other at a neutral point.

The collector of the upper arm switch SWH in each phase is connected to the positive busbar H1. The emitter of the lower arm switch SWL in each phase is connected with the negative busbar L1. The battery pack 30 is connected to the inverter 20 via the positive busbar H1 and the negative busbar L1.

The battery pack 30 of the power supply system 100 includes a first storage battery 31 and a second storage battery 32. The storage batteries 31 and 32 each serve as a power source for driving the rotation of the rotor of the motor 10. Each of the storage batteries 31 and 32 is an assembled battery formed as a series-connection body of single battery cells. The positive terminal of the first storage battery 31 is connected to the positive busbar H1, and the negative terminal of the second storage battery 32 is connected to the negative busbar L1. The battery cells constituting an assembled battery have terminal voltages (e.g., rated voltages) set to, for example, the same value. The battery cells may be, for example, secondary cells, such as lithium-ion cells. The storage batteries 31 and 32 may have either the same or different terminal voltages (e.g., rated voltages).

Each of the storage batteries 31 and 32 can be charged by an external battery charger 40 installed outside the vehicle. The external battery charger 40 may be, for example, a stationary battery charger. The external battery charger 40 may be either a regular charger or a fast charger. The positive terminal of the external battery charger 40 is connected to one end of a positive charging path 43, and the other end of the charging path 43 is connected to the positive busbar H1. The negative terminal of the external battery charger 40 is connected to one end of a negative charging path 44, and the other end of the charging path 44 is connected to the negative busbar L1.

The battery pack 30 of the power supply system 100 includes a positive main switch SMRH that electrically connects or disconnects the positive busbar H1 connecting the first storage battery 31 and the inverter 20. The positive main switch SMRH is installed on the positive busbar H1. The battery pack 30 of the power supply system 100 also includes a negative main switch SMRL that electrically connects or disconnects the negative busbar L1 connecting the second storage battery 32 and the inverter 20. The positive charging path 43 in the power supply system 100 includes a high-potential charging switch DCRH that electrically connects or disconnects the positive charging path 43. The negative charging path 44 in the power supply system 100 includes a low-potential charging switch DCRL that electrically connects or disconnects the negative charging path 44. The positive main switch SMRH, the negative main switch SMRL, the high-potential charging switch DCRH, and the low-potential charging switch DCRL are sometimes collectively referred to as the switches SMRH, SMRL, DCRH, and DCRL.

In the present embodiment, each of the switches SMRH, SMRL, DCRH, and DCRL is a mechanical relay. When turned off, each of the switches SMRH, SMRL, DCRH, and DCRL blocks current flow in both directions. When turned on, the switch allows current flow in both directions. Each of the switches SMRH, SMRL, DCRH, and DCRL may not only be a mechanical relay, but also, for example, a semiconductor switching element.

The battery pack 30 of the power supply system 100 includes a first switch SW1, a second switch SW2, a third switch SW3, and a fourth switch SW4 as switches for changing the connection states of the first storage battery 31 and the second storage battery 32. Hereinafter, the first switch SW1, the second switch SW2, the third switch SW3, and the fourth switch SW4 are sometimes collectively referred to as the switches SW1 to SW4.

In the present embodiment, the switches SW1 to SW4 are mechanical relays. When turned off, the switches SW1 to SW4 block current flow in both directions. When turned on, the switches allow current flow in both directions. The switches SW1 to SW4 may not only be mechanical relays, but also, for example, semiconductor switching elements.

The first switch SW1 is installed on a first electrical path 24 connecting the negative terminal of the first storage battery 31 and the positive terminal of the second storage battery 32. When the first switch SW1 is turned on, the negative terminal of the first storage battery 31 and the positive terminal of the second storage battery 32 are electrically connected. In contrast, when the first switch SW1 is turned off, the negative terminal of the first storage battery 31 and the positive terminal of the second storage battery 32 are electrically disconnected.

The second switch SW2 is installed on a second electrical path 25 connecting the negative terminal of the first storage battery 31 and the negative busbar L1. When the second switch SW2 is turned on, the negative terminal of the first storage battery 31 and the negative busbar L1 are electrically connected. In contrast, when the second switch SW2 is turned off, the negative terminal of the first storage battery 31 and the negative busbar L1 are electrically disconnected.

The third switch SW3 and the fourth switch SW4 are installed on a third electrical path 26 connecting the part of the first electrical path 24 from the first switch SW1 to the second storage battery 32 and the neutral point of the armature windings 11. The third switch SW3 is installed nearer to the second storage battery 32, whereas the fourth switch SW4 is installed nearer to the neutral point. When the third switch SW3 and the fourth switch SW4 are turned on, the neutral point of the armature windings 11 and the positive terminal of the second storage battery 32 are electrically connected. In contrast, when the third switch SW3 or the fourth switch SW4 is turned off, the neutral point of the armature windings 11 and the positive terminal of the second storage battery 32 are electrically disconnected.

The power supply system 100 includes a neutral-point capacitor 22. The high-potential terminal of the neutral-point capacitor 22 is connected to a neutral point (more specifically, a point on the third electrical path 26 between the third switch SW3 and the fourth switch SW4). The low-potential terminal of the neutral-point capacitor 22 is connected to the negative busbar L1.

The power supply system 100 includes various sensors. As shown in FIG. 1, a first current sensor A11 for measuring the current flowing through the first storage battery 31 is installed on the electrical path between the positive main switch SMRH and the first storage battery 31. This sensor may be installed at any site on the electrical path as long as the sensor can measure the current flowing through the first storage battery 31.

In addition, a second current sensor A12 for measuring the current flowing through the second storage battery 32 is installed on the first electrical path 24 between the first switch SW1 and the second storage battery 32 (more specifically, between the point of connection with the third electrical path 26 and the positive terminal of the second storage battery 32). This sensor may be installed at any site on the electrical path as long as the sensor can measure the current flowing through the second storage battery 32. Furthermore, a first voltage sensor V11 for measuring the open-circuit voltage (OCV) of the first storage battery 31 and a second voltage sensor V12 for measuring the OCV of the second storage battery 32 are installed.

Note that the inverter 20 may be contained in the battery pack 30. Some or all of the switches SMRH, SMRL, and SW1 to SW4 may be installed outside the battery pack 30.

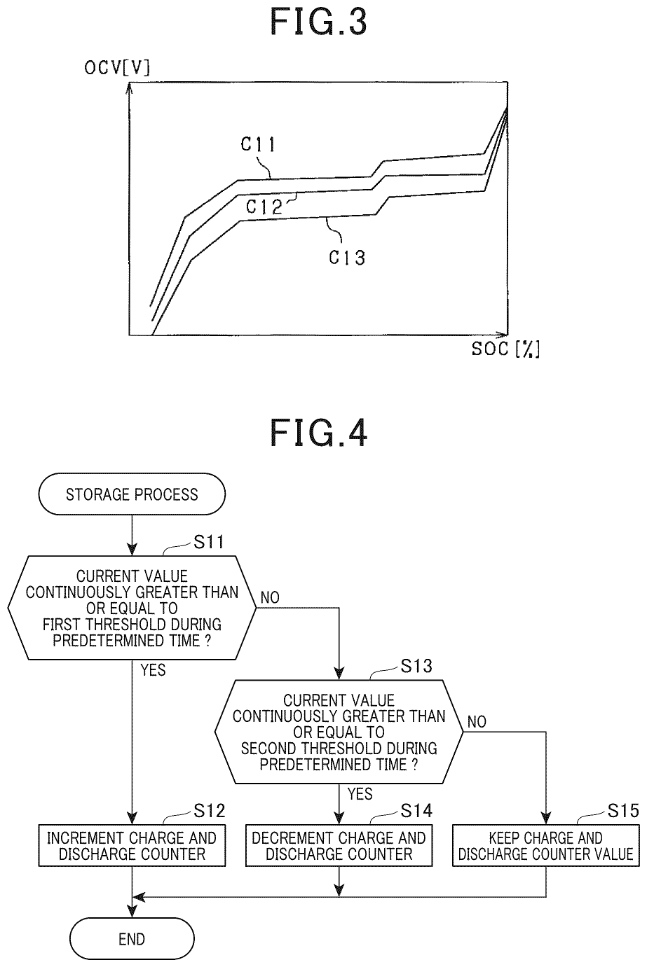

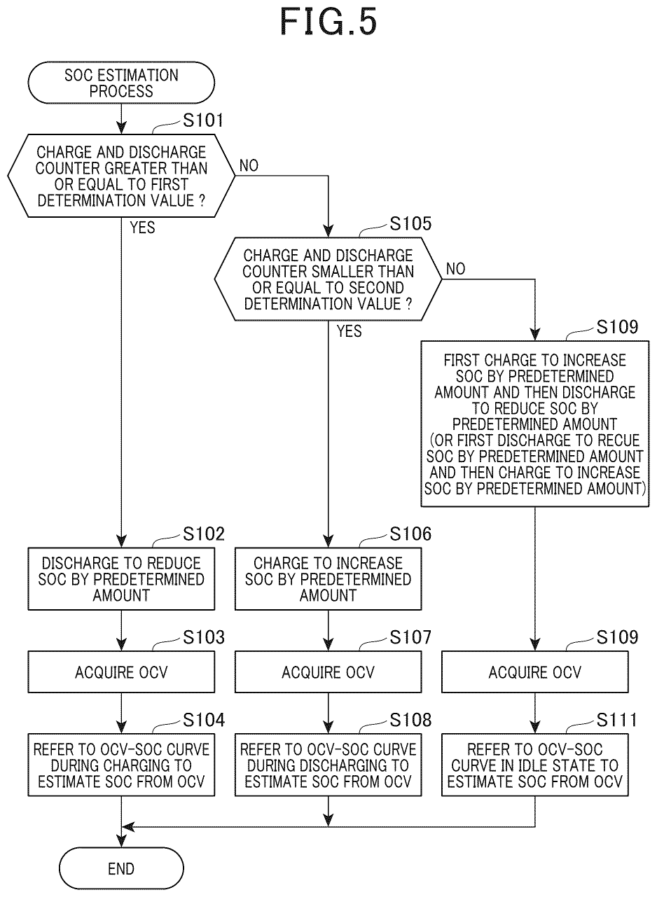

The power supply system 100 includes a control device 50 as a state-of-charge estimation device. The control device 50 is basically a microcomputer, and the microcomputer includes a CPU, a RAM, a ROM, and other components. The functions provided by the control device 50 may be provided by software recorded on a tangible memory device and a computer for executing the software, software alone, hardware alone, or a combination thereof. For example, when provided by an electronic circuit, which is hardware, the microcomputer may be provided by an analog circuit or a digital circuit including a large number of logic circuits. For example, the microcomputer executes programs stored in a non-transitory tangible storage medium such as a memory included in the microcomputer. Examples of the programs include programs for the processing described later, shown in FIGS. 3 and 4 and other figures. When a program is executed, the method (processing) corresponding to the program is implemented. The memory may be, for example, a non-volatile memory. The programs stored in the memory can be updated via a communication network such as an over-the-air (OTA) network or the internet.

The control device 50 receives information (detection values) from various sensors. The various sensors include, for example, the first current sensor A11, the second current sensor A12, the first voltage sensor V11, and the second voltage sensor V12 described above. Although not shown, other examples of the various sensors include a rotation angle sensor that detects the rotation angle (electrical angle) of the rotor and a phase current sensor that detects the phase current flowing through the armature winding 11 in each phase.

The control device 50 executes various processes according to the programs based on information such as detection values received from the various sensors. Examples of the various processes to be executed include a process for controlling the inverter 20. Specifically, the control device 50 controls switches such as the switches SWH and SWL included in the inverter 20 in order to feedback-control the controlled quantity of the motor 10 to match the command value based on detection values from each sensor. The controlled quantity may be for example, torque. In each phase, the upper arm switch SWH and the lower arm switch SWL are alternately turned on. This feedback control transmits the rotational power of the rotor to the drive wheels, driving the vehicle.

To charge the first storage battery 31 and the second storage battery 32 when the external battery charger 40 is connected, the control device 50 controls the on-off state of each of the switches SMRH, SMRL, DCRH, DCRL, and SW1 to SW4 and the switches SWH and SWL included in the inverter 20. For example, when the external battery charger 40 is a fast charger, the control device 50 connects the first storage battery 31 and the second storage battery 32 in series for fast charging. In some cases, the control device 50 connects the first storage battery 31 and the second storage battery 32 in parallel via the neutral point of the motor 10 for charging. In these cases, the control device 50 may use the inverter 20 and the armature windings 11 of the motor 10 as a voltage converter (DC-DC converter) and step up (or step down) the charging voltage from the external battery charger 40 for charging.

The control device 50 also acquires the OCV of each of the storage batteries 31 and 32 and estimates the state of charge (SOC) of each of the storage batteries 31 and 32 from the OCV according to a state-of-charge estimation program.

The OCV and SOC of each of the storage batteries 31 and 32 may differ depending on the usage conditions of the storage batteries 31 and 32. More specifically, depending on the traveling state of the vehicle, the torque demanded for the motor 10 may be greatly changed. Furthermore, the storage batteries 31 and 32 may be charged either by a fast charger or by a regular charger. Thus, the storage batteries 31 and 32 used in the vehicle may experience large variations in the speed of charge or discharge, that is, the C-rate (the ratio of the charge/discharge current value to the battery capacity).

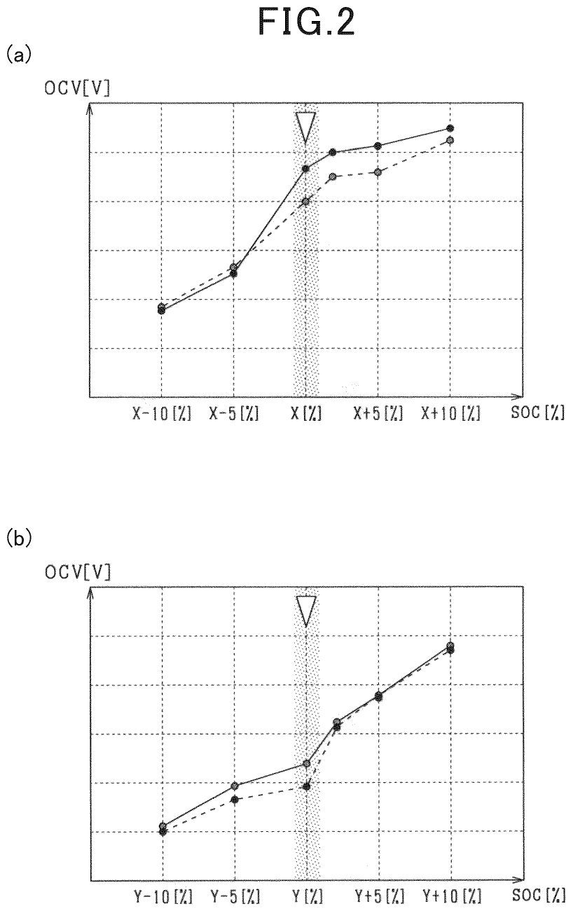

As shown in FIG. 2(a), our studies have revealed that the OCV may vary depending on the C-rate even when the SOC immediately after charge represents the same X % (e.g., 50%). In FIG. 2, the OCV at high C-rates is indicated by a solid line, whereas the OCV at low C-rates is indicated by a dashed line. Similarly, as shown in FIG. 2(b), our studies have revealed that the OCV may vary depending on the C-rate even when the SOC immediately after discharge represents the same Y % (e.g., 50%). It is evident that the SOC cannot be accurately estimated based on OCV values containing an error.

In particular, the OCV-SOC curve (charge and discharge curve) for the storage batteries 31 and 32 is known to have a plateau region, where the curve flattens temporarily, as shown in FIG. 3. When the SOC is estimated in such a plateau region, a slight OCV error may result in a significant SOC error.

As shown in FIG. 3, an OCV-SOC curve C11, which is a charging curve during charge, does not align with an OCV-SOC curve C13, which is a discharging curve during discharge. That is, the storage batteries 31 and 32 have hysteresis characteristics. The SOC thus needs to be estimated also based on the hysteresis characteristics of each of the storage batteries 31 and 32.

The following details the various functions of the control device 50 and various processes executed by the control device 50 to estimate the SOC of each of the storage batteries 31 and 32 from the OCV of each of the storage batteries 31 and 32. The various functions related to SOC estimation are implemented by the microcomputer of the control device 50 executing the program (state-of-charge estimation program) stored in, for example, the memory in the control device 50.

As shown in FIG. 1, examples of the various functions related to SOC estimation include functions as a storage unit 51, a charge and discharge determination unit 52, a charge and discharge control unit 53, an open-circuit voltage acquisition unit 54, and a state-of-charge estimation unit 55. The various functions are described in detail below.

First, the storage unit 51 is described. The storage unit 51 stores the charge and discharge histories of the storage batteries 31 and 32. The charge and discharge histories reflect the charging and discharging trends of the storage batteries 31 and 32. For example, over the period from the previous SOC estimation to the present, the integrated current value calculated by integrating the current flowing into or flowing out of each of the storage batteries 31 and 32 may be stored as the corresponding charge and discharge history.

A charge and discharge history storage process in the present embodiment will now be described with reference to FIG. 4. The control device 50 serving as the storage unit 51 executes a storage process at predetermined intervals. The storage process is executed for each of the storage batteries 31 and 32. Although the storage process for the first storage battery 31 is mainly described below, the same applies to the storage process for the second storage battery 32.

When the storage process is started, as shown in FIG. 4, the control device 50 determines whether the current value of the first storage battery 31 has continuously remained greater than or equal to a first threshold Th1 during a predetermined time (step S11). The current value is represented as a positive value (+) when the current is flowing into the first storage battery 31 (i.e., during charge), whereas the current value is represented as a negative value (−) when the current is flowing out of the first storage battery 31 (i.e., during discharge). Although the predetermined time may be any time, the time may be, for example, the storage process execution interval. The first threshold Th1 is any positive value.

That is, in step S11, it is determined that the battery has been charged by at least the amount of current represented by the absolute value of the first threshold Th1 multiplied by the predetermined time. If the result of the determination is affirmative, the control device 50 increments (adds 1 to) a charge and discharge counter stored in the memory in the control device 50 (step S12). The storage process is then ended.

If the result of the determination in step S11 is negative, the control device 50 determines whether the current value of the first storage battery 31 has continuously remained smaller than or equal to a second threshold Th2 during a predetermined time (step S13). The second threshold Th2 is any negative value. That is, in step S13, it is determined that the battery has been discharged by at least the amount of current represented by the absolute value of the second threshold Th2 multiplied by the predetermined time. If the result of the determination is affirmative, the control device 50 decrements (subtracts 1 from) the charge and discharge counter (step S14). The storage process is then ended.

In contrast, if the result of the determination in step S13 is negative, that is, it cannot be determined that either charging or discharging has been performed, the control device 50 decides to keep the charge and discharge counter value (step S15) and ends the storage process.

The charge and discharge determination unit 52 determines whether each of the storage batteries 31 and 32 is in a charged state or a discharged state based on the charge and discharge history acquired from the storage unit 51. For example, the charge and discharge determination unit 52 may determine that the battery is in a charged state when the integrated current value is within the charging range reflecting a post-charging trend. The charge and discharge determination unit 52 may determine that the battery is in a discharged state when the integrated current value is within the discharging range reflecting a post-discharging trend. The charge and discharge determination unit 52 may determine that the charge/discharge status is unknown when the integrated current value is outside both the charging and discharging ranges.

In the present embodiment, if the charge and discharge counter stored in the storage unit 51 indicates a first determination value J1 or higher representing the charging range, the charge and discharge determination unit 52 determines that the battery is in a charged state. In contrast, if the charge and discharge counter indicates a second determination value J2 or lower representing the discharging range, the charge and discharge determination unit 52 determines that the battery is in a discharged state. When the charge and discharge counter indicates a value higher than the second determination value J2 and lower than the first determination value J1, the charge/discharge status is determined to be unknown.

When the charge and discharge determination unit 52 determines that the first storage battery 31 is in a charged state, the charge and discharge control unit 53 discharges the first storage battery 31. In this case, the control device 50 discharges the first storage battery 31 to reduce the SOC by a predetermined amount (e.g., 5.0%).

In contrast, when the first storage battery 31 is determined to be in a discharged state, the charge and discharge control unit 53 charges the first storage battery 31. In this case, the control device 50 charges the first storage battery 31 to increase the SOC by a predetermined amount (e.g., 2.5%).

The charging amount and the discharging amount may differ as in the present embodiment or may be the same. The charge and discharge speed (C-rate) is predetermined, and in the present embodiment, charge or discharge is performed at a low rate. The amount of charging and discharging current and the C-rate are defined based on experiments so that OCV errors can be effectively reduced.

The charge and discharge determination unit 52 in the present embodiment charges and discharges the first storage battery 31 by allowing power exchange between the first storage battery 31 and the second storage battery 32. Specifically, the control device 50 serving as the charge and discharge determination unit 52 turns on the switches SMRH and SW2 to SW4, controlling the inverter 20 to convert (step up) the voltage of the second storage battery 32. As a result, the discharge power from the second storage battery 32 is supplied to the first storage battery 31, charging the first storage battery 31. Similarly, the control device 50 turns on the switches SMRH and SW2 to SW4, controlling the inverter 20 to convert the voltage of the first storage battery 31. As a result, the discharge power from the first storage battery 31 is supplied to the second storage battery 32, charging the second storage battery 32.

In the present embodiment, the first storage battery 31 is charged and discharged by power exchange between the first storage battery 31 and the second storage battery 32. However, any other method may be used as long as charging and discharging can be performed. For example, the first storage battery 31 may be discharged by supplying power to a predetermined electric load connected to the first storage battery 31. The first storage battery 31 may be charged from the external battery charger 40 and an electric generator (e.g., the motor 10) connected to the first storage battery 31.

The open-circuit voltage acquisition unit 54 acquires the open-circuit voltage (OCV) of the first storage battery 31 after the first storage battery 31 is charged or discharged by the charge and discharge control unit 53. For example, the open-circuit voltage acquisition unit 54 turns off the switches SW1 to SW4 to bring the first storage battery 31 into a no-load state and acquires the open-circuit voltage of the first storage battery 31 from the first voltage sensor V11.

The state-of-charge estimation unit 55 refers to the OCV-SOC curve (charge and discharge curve) indicating the relationship between the OCV of the first storage battery 31 and the SOC of the first storage battery 31, estimating the SOC of the first storage battery 31 from the OCV of the first storage battery 31 acquired by the open-circuit voltage acquisition unit 54.

In the present embodiment, three OCV-SOC curves are prepared as shown in FIG. 3. Specifically, the OCV-SOC curve C11 during charging, an OCV-SOC curve C12 in an idle state (complete idle state), and the OCV-SOC curve C13 during discharging are prepared. The OCV-SOC curve C11 is a charging curve that can be achieved by the SOC as a result of continuous charging from a specified lower limit to a specified upper limit at a predetermined rate of current (C-rate). The OCV-SOC curve C12 is a curve that can be achieved by the SOC as a result of self-discharge from a specified upper limit to a specified lower limit. The OCV-SOC curve C13 is a discharging curve that can be achieved by the SOC as a result of continuous discharging from a specified upper limit to a specified lower limit at a predetermined rate of current (C-rate). The OCV-SOC curves are identified through simulations and experiments and prestored in, for example, the memory in the control device 50.

The control device 50 serving as the state-of-charge estimation unit 55 reads the OCV-SOC curve C11 during charging when the charge and discharge determination unit 52 determines that the first storage battery 31 is in a charged state. The control device 50 then refers to the OCV-SOC curve C11 to estimate the SOC of the first storage battery 31 from the OCV of the first storage battery 31 acquired by the open-circuit voltage acquisition unit 54.

The control device 50 serving as the state-of-charge estimation unit 55 reads the OCV-SOC curve C13 during discharging when the charge and discharge determination unit 52 determines that the first storage battery 31 is in a discharged state. The control device 50 then refers to the OCV-SOC curve C13 to estimate the SOC of the first storage battery 31 from the OCV of the first storage battery 31 acquired by the open-circuit voltage acquisition unit 54.

The control device 50 reads the OCV-SOC curve C12 in the idle state when the charge and discharge determination unit 52 determines that the charge/discharge status is unknown, that is, the first storage battery 31 is neither in a charged state nor a discharged state. The control device 50 then refers to the OCV-SOC curve C12 to estimate the SOC of the first storage battery 31 from the OCV of the first storage battery 31 acquired by the open-circuit voltage acquisition unit 54.

Next, an SOC estimation process for estimating the SOC will be described with reference to FIG. 5. The SOC estimation process is executed by the control device 50 after an SOC estimation instruction signal is input from a higher-level control device and the charging or discharging of the first storage battery 31 is completed. The SOC estimation supply signal is output at a predetermined point in time, for example, when the vehicle stops.

When the SOC estimation process is started, as shown in FIG. 5, the control device 50 determines whether the charge and discharge counter stored in the memory by the storage unit 51 indicates the first determination value J1 or higher, which represents the charging range (step S101).

If the result of the determination is affirmative, the control device 50 discharges the first storage battery 31 to reduce the SOC by a predetermined amount (about 5.0%) (step S102). After the first storage battery 31 is discharged, the control device 50 acquires the OCV of the first storage battery 31 from the first voltage sensor V11 (step S103).

The control device 50 refers to the OCV-SOC curve C11 during charging to estimate the SOC of the first storage battery 31 from the OCV of the first storage battery 31 acquired in step S103 (step S104). The SOC estimation process is then ended.

In contrast, if the result of the determination in step S101 is negative, the control device 50 determines whether the charge and discharge counter stored in the memory by the storage unit 51 indicates the second determination value J2 or lower, which represents the discharging range (step S105). If the result of the determination is affirmative, the control device 50 charges the first storage battery 31 to increase the SOC by a predetermined amount (about 2.5%) (step S106). After the first storage battery 31 is charged, the control device 50 acquires the OCV of the first storage battery 31 from the first voltage sensor V11 (step S107).

The control device 50 refers to the OCV-SOC curve C13 during discharging to estimate the SOC of the first storage battery 31 from the OCV of the first storage battery 31 acquired in step S107 (step S108). The SOC estimation process is then ended.

In contrast, if the result of the determination in step S105 is negative, the control device 50 charges the first storage battery 31 to increase the SOC by a predetermined amount and then discharges the first storage battery 31 to reduce the SOC by a predetermined amount (step S109). In step S109, it is desirable for the charging and discharging amounts to be the same, but these amounts may differ. Note that the control device 50 may first discharge the first storage battery 31 to reduce the SOC by a predetermined amount and then charge the first storage battery 31 to increase the SOC by a predetermined amount.

After the charging and discharging of the first storage battery 31, the control device 50 acquires the OCV of the first storage battery 31 from the first voltage sensor V11 (step S110). The control device 50 then refers to the OCV-SOC curve C12 in the idle state to estimate the SOC of the first storage battery 31 from the OCV of the first storage battery 31 acquired in step S110 (step S111). The SOC estimation process is then ended.

The processing in steps S101 and S105 corresponds to charge and discharge determination processing, and the control device 50 functions as the charge and discharge determination unit 52 by performing the processing. The processing in steps S102, S106, and S109 corresponds to charge and discharge control processing, and the control device 50 functions as the charge and discharge control unit 53 by performing the processing. The processing in steps S103, S107, and S110 corresponds to open-circuit voltage acquisition processing, and the control device 50 functions as the open-circuit voltage acquisition unit 54 by performing the processing. The processing in steps S104, 108, and S111 corresponds to state-of-charge estimation processing, and the control device 50 functions as the state-of-charge estimation unit 55 by the processing.

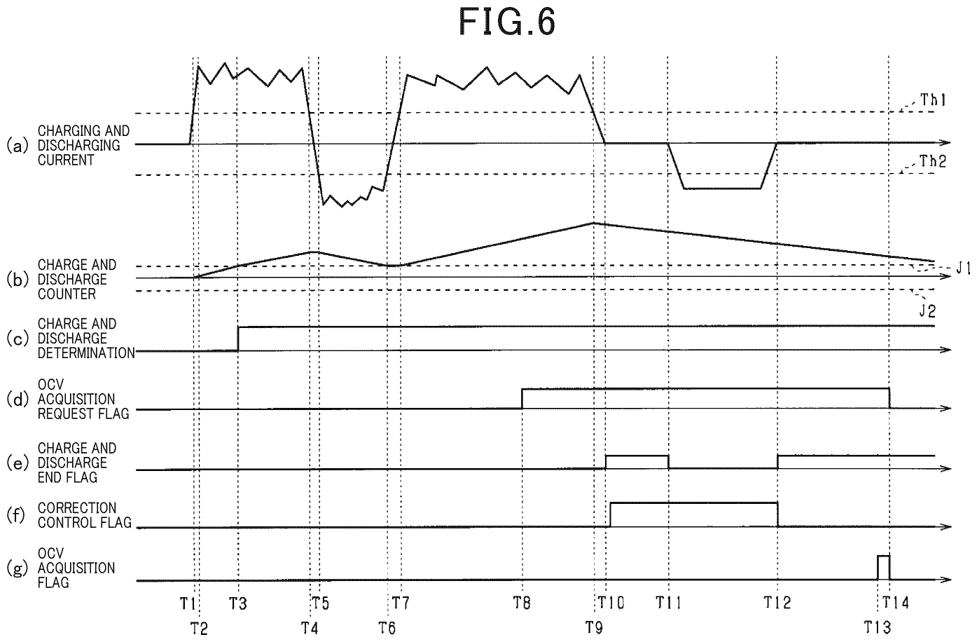

The flow of the SOC estimation process is described with reference to the specific example shown in FIG. 6. FIG. 6(a) shows charge and discharge currents for the first storage battery 31. FIG. 6(b) shows fluctuations in the charge and discharge counter value, and FIG. 6(c) shows the results of charge and discharge determination. In FIG. 6(c), the positive (upper) level indicates the determination that the battery is in a charged state, and the negative (lower) level indicates the determination that the battery is in a discharged state. FIG. 6(d) shows an OCV acquisition request flag, which is turned on (set to a high level) when the SOC estimation process is started, and turned off (set to a low level) when the OCV is acquired. FIG. 6(e) shows a charge and discharge end flag, which is turned off (set to a low level) when the first storage battery 31 is being charged or discharged, and turned on (set to a high level) when the first storage battery 31 is not being charged or discharged. FIG. 6(f) shows a correction control flag, which is turned on (set to a high level) when charge and discharge control is requested for OCV error suppression, and turned off (set to a low level) when the charge and discharge control is completed. The charge and discharge control for OCV error suppression is associated with, for example, the processing in steps S102, S106, and S109. FIG. 6(g) shows an OCV acquisition flag, which is turned on (set to a high level) during the period from the start to the end of the OCV acquisition processing (steps S103, S107, and S110).

As shown in FIGS. 6(a) and 6(b), the charge and discharge counter increases and decreases in accordance with the charge and discharge current value of the first storage battery 31 from time point T1 to time point T10. For example, from time point T2 to T4 and from T7 to T9, the current value of the first storage battery 31 continues to be greater than or equal to the first threshold Th1, and thus the charge and discharge counter increments at fixed intervals of time. Similarly, from time point T5 to T6, the current value of the first storage battery 31 continues to be smaller than or equal to the second threshold Th2, and thus the charge and discharge counter decrements at fixed intervals of time. From time point T1 to T2, T4 to T5, T6 to T7, and T9 to T10, the current value of the first storage battery 31 is greater than the second threshold Th2 and smaller than the first threshold Th1, and thus the charge and discharge counter value is kept.

As shown in FIG. 6(b), at and after time point T3, the charge and discharge counter value is greater than or equal to the first determination value J1. Thus, as shown in FIG. 6(c), the charge and discharge determination results at and after time point T3 indicate that the battery is in a charged state.

As shown in FIG. 6(d), when an SOC estimation instruction signal is input at time point T8, the OCV acquisition request flag is turned on. However, as shown in FIGS. 6(a) and 6(e), since the battery is being charged and discharged (the charge and discharge end flag is not turned on), the SOC estimation process enters a standby state without being started.

Then, at time point T10, when the charging and discharging of the first storage battery 31 end, and the charge and discharge end flag is turned on, the SOC estimation process is started. The correction control flag is accordingly turned on. At time point T11, when a predetermined time has passed since turning on the charge and discharge end flag and the correction control flag, the charge and discharge control is performed to suppress OCV errors. In this state, as shown in FIG. 6(c), because the battery is determined to be in a charged state, the battery is discharged to suppress OCV errors (time point T11 to T12). After that, at time point T13 to T14, processing is performed to acquire the OCV. After the OCV is acquired, the SOC is estimated.

Next, the effects achieved by such processing will be described. As shown in FIG. 2(a), even when the SOC immediately after charge represents the same X %, variations in the C-rate may cause an error in the OCV. Then, however, the OCV error is minimized by discharging the battery to reduce the SOC by a predetermined amount (in FIG. 2(a), by shifting to the left). In this manner, the OCV error due to differences in the C-rate can be minimized.

As shown in FIG. 2(a), it has been found that, even when the first storage battery 31 is determined to be in a charged state, the OCV error can be reduced also by charging the first storage battery 31 to increase the SOC by a predetermined amount (shift to the right). However, as shown in FIG. 2(a), compared with discharging (shifting to the left), charging (shifting to the right) is less effective in correcting errors and needs a larger charging current.

Thus, in the present embodiment, when determined to be in a charged state, the first storage battery 31 is discharged to reduce the SOC by a predetermined amount. This approach can shorten the time needed to correct OCV errors and also minimize fluctuations in the SOC caused by error correction (or error reduction; the same applies hereinafter).

As shown in FIG. 2(b), even when the SOC immediately after discharge represents the same Y %, variations in the C-rate may cause an error in the OCV. Then, however, the OCV error is minimized by charging the battery to increase the SOC by a predetermined amount. In this manner, the OCV error due to differences in the C-rate can be minimized.

As shown in FIG. 2(b), it has been found that, even when the first storage battery 31 is determined to be in a discharged state, the OCV error can be reduced also by discharging the first storage battery 31 to reduce the SOC by a predetermined amount. However, as shown in FIG. 2(b), compared with charging, discharging is less effective in correcting errors and needs a larger discharging current.

Thus, in the present embodiment, when determined to be in a discharged state, the first storage battery 31 is charged to increase the SOC by a predetermined amount. This approach can shorten the time needed to correct OCV errors and also minimize fluctuations in the SOC caused by error reduction.

The effects of the power supply system 100 in the first embodiment will now be described. Although the following mainly describes the effects achieved when the first storage battery 31 is measured, the same effects can be achieved when the second storage battery 32 is measured.

The control device 50 discharges the first storage battery 31 when the first storage battery 31 is determined to be in a charged state, and charges the first storage battery 31 when the first storage battery 31 is determined to be in a discharged state, thereafter detecting and acquiring the OCV of the first storage battery 31. This approach can minimize the OCV error caused by differences in the C-rate. Since the OCV error can be reduced, the SOC error estimated based on the OCV can also be reduced.

The charge and discharge history is an integrated current value calculated by integrating the current flowing into or flowing out of the first storage battery 31. Specifically, the integrated current value is determined by adding 1 to the charge and discharge counter in the case of charging with a predetermined amount of current, and subtracting 1 from the charge and discharge counter in the case of discharging at a predetermined amount of current.

The control device 50 determines that the battery is in a charged state when the integrated current value is within the charging range reflecting a post-charging trend, and determines that the battery is in a discharged state when the integrated current value is within the discharging range reflecting a post-discharging trend. Specifically, when the charge and discharge counter indicates the first determination value J1 or higher, the control device 50 determines that the battery is in a charged state. When the charge and discharge counter indicates the second determination value J2 or lower, the control device 50 determines that the battery is in a discharged state. This enables the usage condition of the first storage battery 31 to be determined accurately because the determination can be based on the charge and discharge history over a certain period.

When the control device 50 fails to determine whether the battery is in a charged state or a discharged state from the charge and discharge history, that is, the result of the determination in step S105 is negative, as indicated in step S109, the first storage battery 31 is first charged and then discharged, or the first storage battery 31 is first discharged and then charged. This approach can minimize the OCV error associated with the C-rate even when the usage condition of the first storage battery 31 is unknown.

As can be seen by comparing FIGS. 2(a) and 2(b), discharging after charging (FIG. 2(a)) is less effective in correcting OCV errors than charging after discharging (FIG. 2(b)). The control device 50 thus determines different amounts of current for discharging the storage battery determined to be in a charged state and discharging the storage battery determined to be in a charged state. Specifically, as indicated in steps S102 and S105, the control device 50 discharges the battery to reduce the SOC by about 5.0% when the battery is determined to be in a charged state, and charges the battery to increase the SOC by about 2.5% when the battery is determined to be in a discharged state. This approach can reduce the amount of charging current and the charging time needed to correct the OCV error in step S105.

If the first storage battery 31 is determined to be in a charged state (the result of the determination in step S101 is affirmative), the control device 50 refers to the OCV-SOC curve C11 during charging to estimate the SOC (step S104). If the first storage battery 31 is determined to be in a discharged state (the result of the determination in step S105 is affirmative), the control device 50 refers to the OCV-SOC curve C13 during discharging to estimate the SOC (step S108). If the usage condition of the first storage battery 31 is determined to be unknown (the results of the determination in steps S101 and S105 are negative), the control device 50 refers to the OCV-SOC curve C12 in the idle state to estimate the SOC (step S111). This approach enables the SOC to be estimated based on the influence of the hysteresis characteristics of the first storage battery 31 during charging and discharging, suppressing SOC errors.

### (Modifications)

Modifications in which part of the design of the power supply system 100 in the above embodiment is modified will now be described.
In the above embodiment, the level of OCV errors varies depending on the integrated current value. Thus, in steps S102 and S105, the control device 50 may determine the amounts of charging and discharging currents based on the integrated current value. That is, when the integrated current value is large, the control device 50 may increase the amounts of charging and discharging currents. When the integrated current value is small, the control device 50 may reduce the amounts of charging and discharging currents. For example, when the absolute value of the charge and discharge counter indicating the integrated current value is large, the control device 50 may increase the amounts of charging and discharging currents compared with the case in which the absolute value is small.
In the above embodiment, due to the hysteresis characteristics of the storage batteries 31 and 32, the OCV-SOC curve (charge and discharge curve) varies depending on the usage conditions of the storage batteries 31 and 32, that is, the amounts of current with which the batteries have been charged and discharged. Thus, four or more OCV-SOC curves may be prepared and associated with integrated current values, and the associated OCV-SOC curves may be identified by the corresponding integrated current values.

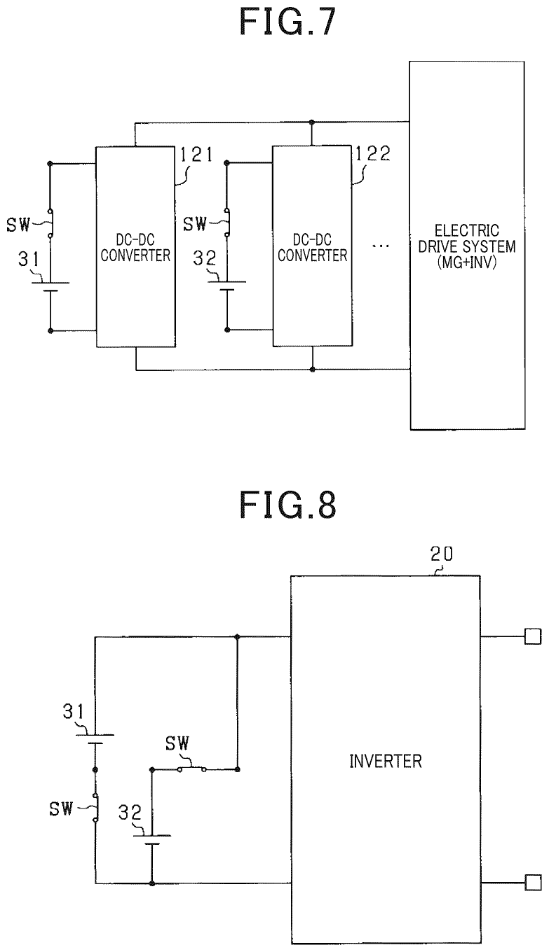

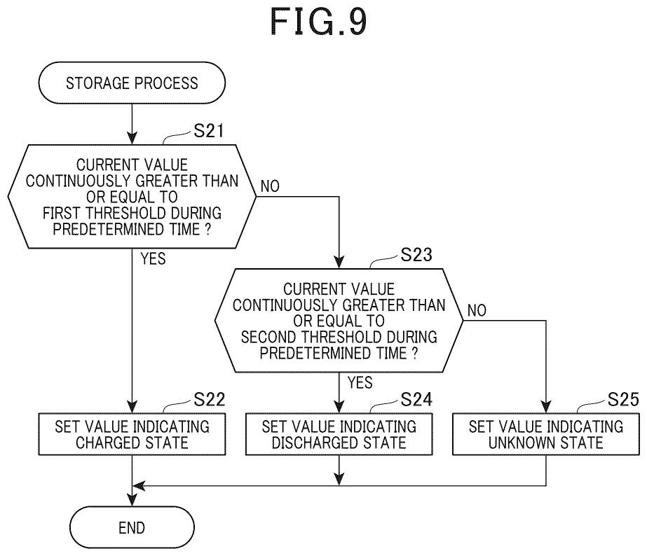

For example, with four or more OCV-SOC curves stored in association with charge and discharge counter values indicating integrated current values, the control device 50 in steps S104, S108, and S111 may use the charge and discharge counter value indicating the integrated current value to identify the corresponding OCV-SOC curve and estimate the SOC based on the identified charge and discharge curve.
In the above embodiment, either of the storage batteries 31 and 32 may be used, or three or more storage batteries may be used. As shown in FIG. 7, the motor 10 and the inverter 20 may be replaced with DC-DC converters 121 and 122 for voltage conversion. As shown in FIG. 8, the storage batteries 31 and 32 may be connected in parallel with the inverter 20 without using the motor 10.
In the storage process in the above embodiment, the results are accumulated. However, the battery status may be determined based on the latest result. Specifically, the storage process shown in FIG. 9 may be adopted. The process is described in detail below. Upon start of the storage process shown in FIG. 9 according to a modification, the control device 50 determines whether the current value of the first storage battery 31 has continuously remained greater than or equal to the first threshold Th1 during a predetermined time (step S21). That is, in step S21, it is determined that the battery has been charged by the amount of current represented by the absolute value of the first threshold Th1 multiplied by the predetermined time. If the result of the determination is affirmative, the control device 50 sets a value indicating that the battery is in a charged state (e.g., 1) to the charge and discharge counter stored in the memory in the control device 50 (step S22). The storage process is then ended.

If the result of the determination in step S21 is negative, the control device 50 determines whether the current value of the first storage battery 31 has continuously remained smaller than or equal to the second threshold Th2 during a predetermined time (step S23). That is, in step S23, it is determined that the battery has been discharged by the amount of current represented by the absolute value of the second threshold Th2 multiplied by the predetermined time. If the result of the determination is affirmative, the control device 50 sets a value indicating that the battery is in a discharged state (e.g., −1) to the charge and discharge counter (step S24). The storage process is then ended.

In contrast, if the result of the determination in step S23 is negative, that is, it cannot be determined that either charging or discharging has been performed, the control device 50 sets a value indicating that the battery status is unknown (e.g., zero) to the charge and discharge counter (step S25), and ends the storage process. In the SOC estimation process, the charge and discharge counter value is used to determine whether the battery status is charged, discharged, or unknown, and the determination result is used for charge and discharge control and OCV-SOC curve identification. This approach enables the charge and discharge history to be stored through simple control.
In the above embodiment, the integrated current value may be measured by a well-known method and used as a charge and discharge history.

The control unit and the control method described in the present disclosure may be implemented by a special purpose computer including memory and a processor programmed to execute one or more functions embodied by computer programs. Alternatively, the control unit and the control method described in the present disclosure may be implemented by a special purpose computer including a processor having one or more dedicated hardware logic circuits. Alternatively, the control unit and the control method described in the present disclosure may be implemented by one or more special purpose computers including a combination of memory and a processor programmed to execute one or more functions and a processor having one or more hardware logic circuits. The computer programs may be stored in a non-transitory, tangible computer readable storage medium as instructions executed by a computer.

The following describes characteristic configurations extracted from the embodiments described above.

### [Configuration 1]

A state-of-charge estimation device (50) for estimating the state of charge of a storage battery, the state-of-charge estimation device comprising:
a storage unit (51) that stores the charge and discharge history of the storage battery;
a charge and discharge determination unit (52) that determines whether the storage battery is in a charged state or a discharged state, based on the charge and discharge history stored in the storage unit;
a charge and discharge control unit (53) that discharges the storage battery by a predetermined amount when the charge and discharge determination unit determines that the storage battery is in a charged state, and charges the storage battery by a predetermined amount when the charge and discharge determination unit determines that the storage battery is in a discharged state;
an open-circuit voltage acquisition unit (54) that acquires the open-circuit voltage of the storage battery after the charge and discharge control unit charges or discharges the storage battery; and
a state-of-charge estimation unit (55) that refers to a charge and discharge curve indicating the relationship between the open-circuit voltage of the storage battery and the state of charge of the storage battery to estimate the state of charge of the storage battery from the open-circuit voltage acquired by the open-circuit voltage acquisition unit.

### [Configuration 2]

The state-of-charge estimation device according to configuration 1, in which
the charge and discharge history is an integrated current value calculated by integrating the current flowing into or flowing out of the storage battery, and
the charge and discharge determination unit determines that the battery is in a charged state when the integrated current value is within the charging range reflecting a post-charging trend, and determines that the battery is in a discharged state when the integrated current value is within the discharging range reflecting a post-discharging trend.

### [Configuration 3]

The state-of-charge estimation device according to configuration 2, in which
the charge and discharge control unit determines the amounts of charging and discharging currents based on the integrated current value.

### [Configuration 4]

The state-of-charge estimation device according to configuration 2, in which
each integrated current value is associated with the corresponding charge and discharge curve in advance, and
the state-of-charge estimation unit identifies the corresponding charge and discharge curve from the associated integrated current value and estimates the state of charge based on the identified charge and discharge curve.

### [Configuration 5]

The state-of-charge estimation device according to any one of configurations 1 to 4, in which
when the charge and discharge determination unit fails to determine whether the battery is in a charged state or a discharged state from the charge and discharge history, the charge and discharge control unit first charges the storage battery and then discharges the storage battery by a predetermined amount, or first discharges the storage battery and then charges the storage battery by a predetermined amount.

### [Configuration 6]

The state-of-charge estimation device according to any one of configurations 1 to 5, in which
the charge and discharge control unit determines different amounts of current for discharging the storage battery determined to be in a charged state and discharging the storage battery determined to be in a charged state.

### [Configuration 7]

The state-of-charge estimation device according to any one of configurations 1 to 6, in which
when the charge and discharge determination unit determines that the storage battery is in a charged state, the state-of-charge estimation unit refers to the charging curve indicating the relationship between the open-circuit voltage and the state of charge during charging to estimate the state of charge, whereas when the charge and discharge determination unit determines that the storage battery is in a discharged state, the state-of-charge estimation unit refers to the discharging curve indicating the relationship between the open-circuit voltage and the state of charge during discharging to estimate the state of charge.

### [Configuration 8]

A state-of-charge estimation system (100) that includes a first storage battery and a second storage battery and estimates the states of charge of the first storage battery and the second storage battery, the state-of-charge estimation system comprising:
a storage unit (51) that stores the charge and discharge history of each of the storage batteries;
a charge and discharge determination unit (52) that determines, for each of the storage batteries, whether each of the storage batteries is in a charged state or a discharged state, based on the charge and discharge history stored in the storage unit;
a charge and discharge control unit (53) that discharges the storage battery determined to be in a charged state by the charge and discharge determination unit, and charges the storage battery determined to be in a discharged state by the charge and discharge determination unit;
an open-circuit voltage acquisition unit (54) that acquires the open-circuit voltage of each of the storage batteries after the charge and discharge control unit charges or discharges each of the storage batteries; and
a state-of-charge estimation unit (55) that refers to a charge and discharge curve indicating the relationship between the open-circuit voltage of the storage battery and the state of charge of the storage battery to estimate the state of charge of each of the storage batteries from the open-circuit voltage of the corresponding storage battery acquired by the open-circuit voltage acquisition unit,
in which the charge and discharge control unit charges and discharges each of the storage batteries by allowing power exchange between the first storage battery and the second storage battery.

### [Configuration 9]

A state-of-charge estimation program for causing a state-of-charge estimation device (50) to perform:
storage processing for storing the charge and discharge history of the storage battery;
charge and discharge determination processing for determining whether the storage battery is being charged or discharged, based on the charge and discharge history stored in the storage unit;
charge and discharge control processing for discharging the storage battery when the charge and discharge determination unit determines that the storage battery is being charged, and charging the storage battery when the charge and discharge determination unit determines that the storage battery is being discharged;
open-circuit voltage acquisition processing for acquiring the open-circuit voltage of the storage battery after the charge and discharge control unit charges or discharges the storage battery; and
state-of-charge estimation processing for referring to a charge and discharge curve indicating the relationship between the open-circuit voltage of the storage battery and the state of charge of the storage battery to estimate the state of charge of the storage battery from the open-circuit voltage acquired by the open-circuit voltage acquisition unit.

Although the present disclosure has been described in accordance with embodiments, it will be understood that the disclosure is not limited to the embodiments or structures described above. The disclosure encompasses various modifications and alterations falling within the range of equivalence. Additionally, various combinations and forms as well as other combinations and forms with one, more than one, or less than one element added thereto also fall within the scope and spirit of the present disclosure.

### CONCLUSION

The present disclosure provides a state-of-charge estimation device that can achieve higher accuracy in the determination of the state of charge of a storage battery, a state-of-charge estimation system, and a state-of-charge estimation program.

First means of the present disclosure is a state-of-charge estimation device for estimating the state of charge of a storage battery. The state-of-charge estimation device includes: a storage unit that stores the charge and discharge history of the storage battery; a charge and discharge determination unit that determines whether the storage battery is in a charged state or a discharged state, based on the charge and discharge history stored in the storage unit; a charge and discharge control unit that discharges the storage battery by a predetermined amount when the charge and discharge determination unit determines that the storage battery is in a charged state, and charges the storage battery by a predetermined amount when the charge and discharge determination unit determines that the storage battery is in a discharged state; an open-circuit voltage acquisition unit that acquires the open-circuit voltage of the storage battery after the charge and discharge control unit charges or discharges the storage battery; and a state-of-charge estimation unit that refers to a charge and discharge curve indicating the relationship between the open-circuit voltage of the storage battery and the state of charge of the storage battery to estimate the state of charge of the storage battery from the open-circuit voltage acquired by the open-circuit voltage acquisition unit.

This can suppress errors in open-circuit voltage caused by differences in the usage conditions of a storage battery, resulting in higher accuracy in the determination of the state of charge of the storage battery.

Second means for solving the above problem is a state-of-charge estimation system that includes a first storage battery and a second storage battery and estimates the states of charge of the first storage battery and the second storage battery. The state-of-charge estimation system includes: a storage unit that stores the charge and discharge history of each of the storage batteries; a charge and discharge determination unit that determines, for each of the storage batteries, whether each of the storage batteries is in a charged state or a discharged state, based on the charge and discharge history stored in the storage unit; a charge and discharge control unit that discharges the storage battery determined to be in a charged state by the charge and discharge determination unit, and charges the storage battery determined to be in a discharged state by the charge and discharge determination unit; an open-circuit voltage acquisition unit that acquires the open-circuit voltage of each of the storage batteries after the charge and discharge control unit charges or discharges each of the storage batteries; and a state-of-charge estimation unit that refers to a charge and discharge curve indicating the relationship between the open-circuit voltage of the storage battery and the state of charge of the storage battery to estimate the state of charge of each of the storage batteries from the open-circuit voltage of the corresponding storage battery acquired by the open-circuit voltage acquisition unit. The charge and discharge control unit charges and discharges each of the storage batteries by allowing power exchange between the first storage battery and the second storage battery.

This can suppress errors in open-circuit voltage caused by differences in the usage conditions of a storage battery, resulting in higher accuracy in the determination of the state of charge of the storage battery.

Third means for solving the above problem is a state-of-charge estimation program for causing a state-of-charge estimation device for estimating the state of charge of a storage battery to perform: storage processing for storing the charge and discharge history of the storage battery; charge and discharge determination processing for determining whether the storage battery is being charged or discharged, based on the charge and discharge history stored by the storage processing; charge and discharge control processing for discharging the storage battery when the charge and discharge determination processing determines that the storage battery is being charged, and charging the storage battery when the charge and discharge determination processing determines that the storage battery is being discharged; open-circuit voltage acquisition processing for acquiring the open-circuit voltage of the storage battery after the charge and discharge control processing charges or discharges the storage battery; and state-of-charge estimation processing for referring to a charge and discharge curve indicating the relationship between the open-circuit voltage of the storage battery and the state of charge of the storage battery to estimate the state of charge of the storage battery from the open-circuit voltage acquired by the open-circuit voltage acquisition processing.

This can suppress errors in open-circuit voltage caused by differences in the usage conditions of a storage battery, resulting in higher accuracy in the determination of the state of charge of the storage battery.

What is claimed is:

1. A state-of-charge estimation device for estimating a state of charge of a storage battery, the state-of-charge estimation device comprising:
a storage unit configured to store a charge and discharge history of the storage battery;
a charge and discharge determination unit configured to determine whether the storage battery is in a charged state or a discharged state, based on the charge and discharge history stored in the storage unit;
a charge and discharge control unit configured to discharge the storage battery by a predetermined amount when the charge and discharge determination unit determines that the storage battery is in a charged state, and charge the storage battery by a predetermined amount when the charge and discharge determination unit determines that the storage battery is in a discharged state;
an open-circuit voltage acquisition unit configured to acquire an open-circuit voltage of the storage battery after the charge and discharge control unit charges or discharges the storage battery; and
a state-of-charge estimation unit configured to refer to a charge and discharge curve indicating a relationship between the open-circuit voltage of the storage battery and the state of charge of the storage battery to estimate the state of charge of the storage battery from the open-circuit voltage acquired by the open-circuit voltage acquisition unit.

2. The state-of-charge estimation device according to claim 1, wherein
the charge and discharge history is an integrated current value calculated by integrating a current flowing into or flowing out of the storage battery, and
the charge and discharge determination unit determines that the battery is in a charged state when the integrated current value is within a charging range reflecting a post-charging trend, and determines that the battery is in a discharged state when the integrated current value is within a discharging range reflecting a post-discharging trend.

3. The state-of-charge estimation device according to claim 2, wherein
the charge and discharge control unit determines amounts of charging and discharging currents based on the integrated current value.

4. The state-of-charge estimation device according to claim 2, wherein
each integrated current value is associated with a corresponding charge and discharge curve in advance, and
the state-of-charge estimation unit identifies the corresponding charge and discharge curve from the associated integrated current value and estimates the state of charge based on the identified charge and discharge curve.

5. The state-of-charge estimation device according to claim 1, wherein
when the charge and discharge determination unit fails to determine whether the battery is in a charged state or a discharged state from the charge and discharge history, the charge and discharge control unit first charges the storage battery and then discharges the storage battery by a predetermined amount, or first discharges the storage battery and then charges the storage battery by a predetermined amount.

6. The state-of-charge estimation device according to claim 1, wherein
the charge and discharge control unit determines different amounts of current for discharging the storage battery determined to be in a charged state and discharging the storage battery determined to be in a charged state.

7. The state-of-charge estimation device according to claim 1, wherein
when the charge and discharge determination unit determines that the storage battery is in a charged state, the state-of-charge estimation unit refers to a charging curve indicating a relationship between the open-circuit voltage and the state of charge during charging to estimate the state of charge, whereas when the charge and discharge determination unit determines that the storage battery is in a discharged state, the state-of-charge estimation unit refers to a discharging curve indicating a relationship between the open-circuit voltage and the state of charge during discharging to estimate the state of charge.

8. A state-of-charge estimation system that includes a first storage battery and a second storage battery and estimates states of charge of the first storage battery and the second storage battery, the state-of-charge estimation system comprising:
a storage unit configured to store a charge and discharge history of each of the storage batteries;
a charge and discharge determination unit configured to determine, for each of the storage batteries, whether each of the storage batteries is in a charged state or a discharged state, based on the charge and discharge history stored in the storage unit;
a charge and discharge control unit configured to discharge the storage battery determined to be in a charged state by the charge and discharge determination unit, and charge the storage battery determined to be in a discharged state by the charge and discharge determination unit;
an open-circuit voltage acquisition unit configured to acquire an open-circuit voltage of each of the storage batteries after the charge and discharge control unit charges or discharges each of the storage batteries; and
a state-of-charge estimation unit configured to refer to a charge and discharge curve indicating a relationship between the open-circuit voltage of the storage battery and the state of charge of the storage battery to estimate the state of charge of each of the storage batteries from the open-circuit voltage of the corresponding storage battery acquired by the open-circuit voltage acquisition unit,
wherein the charge and discharge control unit charges and discharges each of the storage batteries by allowing power exchange between the first storage battery and the second storage battery.

9. A state-of-charge estimation program for causing a state-of-charge estimation device for estimating a state of charge of a storage battery to perform:
storage processing for storing a charge and discharge history of the storage battery;
charge and discharge determination processing for determining whether the storage battery is being charged or discharged, based on the charge and discharge history stored by the storage processing;
charge and discharge control processing for discharging the storage battery when the charge and discharge determination processing determines that the storage battery is being charged, and charging the storage battery when the charge and discharge determination processing determines that the storage battery is being discharged;
open-circuit voltage acquisition processing for acquiring an open-circuit voltage of the storage battery after the charge and discharge control processing charges or discharges the storage battery; and
state-of-charge estimation processing for referring to a charge and discharge curve indicating a relationship between open-circuit voltage of the storage battery and the state of charge of the storage battery to estimate the state of charge of the storage battery from the open-circuit voltage acquired by the open-circuit voltage acquisition processing.
